(19) United States
(12) Patent Application Publication
(10) Pub. No.: US 2025/0240355 A1
(43) Pub. Date: Jul. 24, 2025

(54) CONNECTIVITY SYNTHESIS OF NETWORK-ON-CHIP (NoC) IN A MULTI-PROTOCOL SYSTEM-ON-CHIP (SOC)

(71) Applicant: ARTERIS, INC., Campbell, CA (US)

(72) Inventors: K. Charles JANAC, Campbell, CA (US); Vincent THIBAUT, Jacou (FR); Benoit de LESCURE, Campbell, CA (US)

(73) Assignee: ARTERIS, INC., Campbell, CA (US)

(21) Appl. No.: 19/175,182

(22) Filed: Apr. 10, 2025

Related U.S. Application Data
(63) Continuation of application No. 17/665,578, filed on Feb. 6, 2022, now Pat. No. 12,289,384.
(60) Provisional application No. 63/149,184, filed on Feb. 12, 2021.

(51) Int. Cl. H04L 69/08; G06F 15/78; H04L 69/18

(52) U.S. Cl. CPC H04L 69/08; G06F 15/7825; H04L 69/18

(57) ABSTRACT

In accordance with the various aspects and embodiment of the invention, a design tool is disclosed that automates the process of generating protocol converters using machine-readable descriptions of the external hardware components interfaces and the associated protocols for the IP blocks and the network-on-chip (NoC). One advantage of the invention is lowered mistakes in generating the protocol converters. Another advantage is increased productivity when designing the NoC used in a system-on-chip (SoC).

### CROSS REFERENCE TO RELATED APPLICATION

This application is a continuation of U.S. application Ser. No. 17/665,578 filed on Feb. 6, 2022 and titled SYSTEM AND METHOD FOR SYNTHESIS OF CONNECTIVITY TO AN INTERCONNECT IN A MULTI-PROTOCOL SYSTEM-ON-CHIP (SoC) by K. Charles JANAC, et. al, which claims priority to U.S. Provisional Application Ser. No. 63/149,184 filed on Feb. 12, 2021 and titled PACKET BASED INTERCONNECT IN A SYSTEM-ON-CHIP (SoC) by K. Charles JANAC, et. al, the entire disclosures of which are incorporated herein by reference.

### FIELD OF THE INVENTION

The present technology is in the field of computer system design and, more specifically, related to protocol conversion for a network-on-chip interconnect used in a system-on-chip (SoC).

### BACKGROUND

Networks-on-chip (NoCs) are interconnects that are used to connect IP blocks that exist in a system-on-chip (SoC). The process of creating packet-based interconnects for SoC, which need to communicate with many IP blocks and hardware components, use interfaces with different communication protocols. The protocols used by the IP blocks and hardware components are typically different from the protocol used by the interconnect. The protocol converters are part of the overall design process. The known processes of designing and setting conversion from one protocol to another is an inefficient process.

Thus, there is a challenge of accurately and efficiently connecting an external hardware element or IP block, which uses a particular physical interface (made of a set of pins) and a communication protocol, to the NoC interconnect thereby allowing for exchange of requests and responses with other IP blocks and components of the SoC. The challenge also includes the difference between the IP block communication protocol and conversion to a packet-based NoC interconnect that uses a different communication protocol internally.

When connecting multiple IP blocks, due to distance between IP blocks. limited range of IP block to drive a signal, and signal routing congestion (e.g., not enough physical space to route every signal of each block), it can be advantageous to connect the IP blocks with a NoC. A challenge the system designer faces is to create a protocol converter block to go between the IP block and the protocol used internally in the NoC, and connecting all these components. The challenge is made even more complex when the system designer has to manage the different interfaces implemented by each IP block. A system designer must manually mange each IP blocks protocol, the NoC internal protocol, the pins for the IP block and the NoC, and the connections both between the IP blocks and NoC and the internal NoC connections. This manually management is both time consuming and error prone which increases the cost of a NoC and the risk of an SoC not performing as expected due to a design error.

Therefore, what is needed is a system and method that increases the efficiency and automates the process of generating protocol converters using machine-readable descriptions of the external hardware components interfaces and the associated protocol.

### SUMMARY OF THE INVENTION

In accordance with the various aspects and embodiment of the invention, a system and method are disclosed that automate the process of generating protocol converters using machine-readable descriptions of the external hardware components interfaces and the associated protocol. One advantage of the invention is lowered mistakes in generating the protocol converters. Another advantage is increased productivity when designing the interconnect, such as a network-on-chip (NoC) and assembling the system-on-chip (SoC).

### BRIEF DESCRIPTION OF THE DRAWINGS

In order to understand the invention more fully, reference is made to the accompanying drawings. The invention is described in accordance with the aspects and embodiments in the following description with reference to the drawings or figures (FIG.), in which like numbers represent the same or similar elements. Understanding that these drawings are not to be considered limitations in the scope of the invention, the presently described aspects and embodiments and the presently understood best mode of the invention are described with additional detail through use of the accompanying drawings.

FIG. 1 shows a system in accordance with the various aspects and embodiments of the invention.

FIG. 2 shows a process in accordance with the various embodiment and aspects of the invention.

FIG. 3 shows a process for creating a protocol converter block in accordance with various aspects and embodiments of the invention.

FIG. 4 shows a process for creating a protocol converter block in accordance with various aspects and embodiments of the invention.

FIG. 5 shows a system for generating and creating a protocol converter block in accordance with various aspects and embodiments of the invention.

### DETAILED DESCRIPTION

The following describes various examples of the present technology that illustrate various aspects and embodiments of the invention. Generally, examples can use the described aspects in any combination. All statements herein reciting principles, aspects, and embodiments as well as specific examples thereof, are intended to encompass both structural and functional equivalents thereof. The examples provided are intended as non-limiting examples. Additionally, it is intended that such equivalents include both currently known equivalents and equivalents developed in the future, i.e., any elements developed that perform the same function, regardless of structure.

It is noted that, as used herein, the singular forms “a,” “an” and “the” include plural referents unless the context clearly dictates otherwise. Reference throughout this specification to “one embodiment,” “an embodiment,” “certain embodiment,” “various embodiments,” or similar language means that a particular aspect, feature, structure, or characteristic described in connection with the embodiment is included in at least one embodiment of the invention.

Thus, appearances of the phrases “in one embodiment,” “in at least one embodiment,” “in an embodiment,” “in certain embodiments,” and similar language throughout this specification may, but do not necessarily, all refer to the same embodiment or similar embodiments. Furthermore, aspects and embodiments of the invention described herein are merely exemplary, and should not be construed as limiting of the scope or spirit of the invention as appreciated by those of ordinary skill in the art. The disclosed invention is effectively made or used in any embodiment that includes any novel aspect described herein. All statements herein reciting principles, aspects, and embodiments of the invention are intended to encompass both structural and functional equivalents thereof. It is intended that such equivalents include both currently known equivalents and equivalents developed in the future. Furthermore, to the extent that the terms “including”, “includes”, “having”, “has”, “with”, or variants thereof are used in either the detailed description and the claims, such terms are intended to be inclusive in a similar manner to the term “comprising.”

The terms “source,” “master,” and “initiator” refer to hardware intellectual property (IP) modules/blocks or units; these terms are used interchangeably within the scope and embodiments of the invention. As used herein, the terms “sink,” “slave,” and “target” refer to hardware IP modules or units and the terms are used interchangeably within the scope and embodiments of the invention. As used herein, a transaction may be a request transaction or a response transaction. Examples of request transactions include write request and read request.

Various references are made herein to integrated circuits (ICs) and the designs of ICs. One example of an IC is a multiprocessor system that is implemented in systems-on-chip (SoCs) that communicates through networks-on-chip (NoC), which is an interconnect. The SoCs include instances of initiator intellectual properties (IPs) and target IPs. The IP elements or blocks includes pins that have names and connect to the NoC's pins. The NoC pins also have names. Transactions are sent from an initiator to one or more targets using industry-standard protocols. The initiator, which is connected to the NoC, sends a request transaction to a target or targets, using a protocol. The transaction includes an address that identifies or selects the target or targets. The protocol used by one IP can vary from the protocol used by another IP; both can be different from the protocol used by the NoC or interconnect. The NoC includes network interface units (NIU) that act as protocol converters, which are at the boundary of the NoC and convert (decode) from a protocol (of an external device connected to the pins of the NoC) to the internal protocol of the NoC in accordance with various embodiments and aspects of the invention. The NoC decodes the address at the boundary (where the NIUs are located) and transports the request through the NoC to another NIU located at the boundary of the NoC, which other NIU is in communication with the target (destination). The transaction is converted from the NoC's protocol to the target's protocol at the NIU or the boundary of the NoC. The target receives and handles the transaction. The target then sends a response transaction, which is transported back by the NoC to the initiator. As such, the SoC and NoC include complexity and configurability, especially in situation when the NoC is configurable.

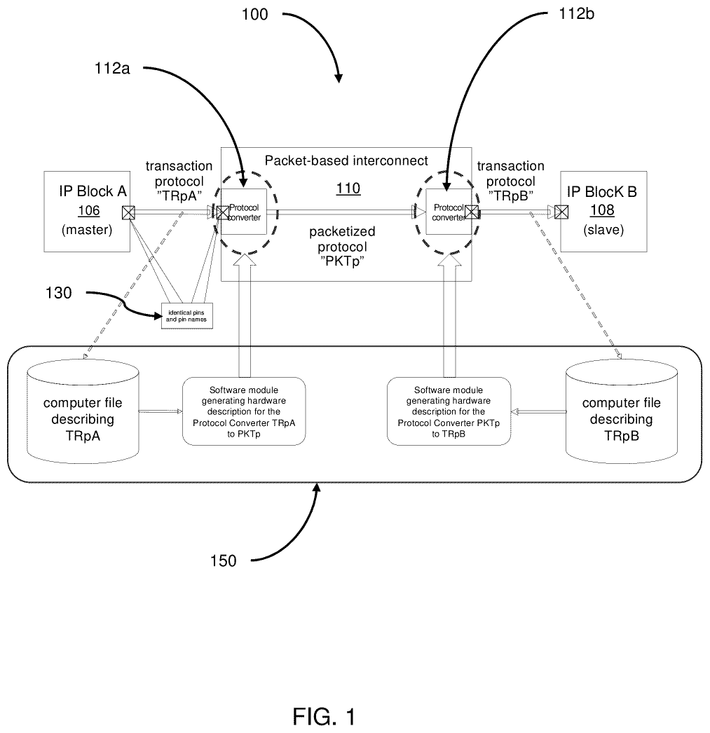

Referring now to FIG. 1, a system 100 is shown with IP block A 106 in communication with IP block B 108 through a Network-on-Chip (NoC) interconnect 110 in accordance with the various aspects and embodiments of the invention. Protocol converters 112 (shown as protocol converter 112a and 112b) are used for the connection of the external hardware element (such as IP block A 106 and IP block B 108) to the interconnect 110. In accordance with some embodiments of the invention, the protocol converter 112 is a hardware component that translate requests and responses presented by IP blocks or the external hardware element, which is using its own protocol, to the protocol of the interconnect 110, which is using a different protocol. In accordance with one aspect and embodiment of the invention, requests and responses, coming to and from, respectively, the interconnect 110 are packet-based and are converted to and from the interconnect 110's protocol. In accordance with some aspect and embodiment of the invention, the protocol converter 112 exposes on the IP block or external hardware component side, the same pins 130 (identical pins and pin names) as the ones used by the external hardware component interface. Thus, the naming convention is consistent, efficient, and avoids mistakes. In accordance with the various aspects of the invention, the naming convention is used in order to determine the connectivity of the IP block pins with the interconnect pins, even though there are different protocols being used.

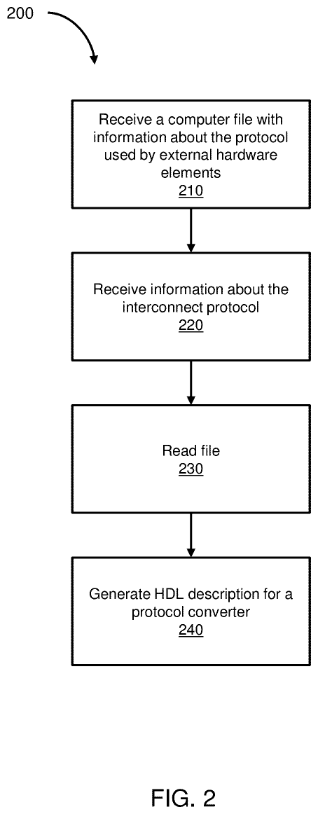

Referring now to FIG. 1 and FIG. 2, a process 200 is shown for generating a protocol converter in accordance with various aspects and embodiments of the invention. As shown in block 150, the protocol used by the external hardware element is described in a computer file. The format of the file does not limit the scope of the invention and, hence, is not specified. The format of the file, for non-limiting examples in accordance with one aspect of the invention, may include a format based on XML with a defined semantic to describe interfaces and associated communication protocols. The level of the protocol description does not limit the scope of the invention; it can be as simple as a reference to a well-known protocol such as AMBA-AXI; or as complex as detailing the protocol behavior.

Referring specifically to FIG. 2, at step 210, the process 200 receives the computer file, which includes information about the protocol used by the external hardware elements, such as IP blocks and IP block protocol. The information includes hardware information, such IP block pin names. At step 220, the process receives information about the interconnect and the interconnect protocol. The information may be in a format. In accordance with some aspects of the invention, the information includes interconnect pin names and interconnect packet-based protocol. At step 230, the process reads the computer file, which has the requirements for generating the corresponding protocol converter; the file is processed to determine the way that the file describes protocols. In accordance with the various aspects of the invention, at step 240, the method produces the hardware description of the protocol converter, in the form of a Hardware Description Language (HDL) file, suitable for implementation as actual hardware using standard ASIC implementation flows.

In accordance with the various aspects and embodiments of the invention, the process produces other collaterals to help with the ASIC implementation flow, such as, for instance: synthesis scripts, integration-oriented XML files, gates, and power estimates and so on. In accordance with some aspects and embodiments of the invention, the protocol converter is integrated in a network interface unit (NIU) of the packet-based interconnect. The NIU and enables communication with the external hardware element, which uses a different protocol. In accordance with some aspects and embodiments of the invention, the protocol converter uses the same pins and the same pin names as the ones used by the IP block or the external hardware element. Thus, connection of pins of the external hardware element to the pins of the protocol converter is straightforward because pins with identical names connect to each other.

Based on the process being implement in accordance with the various aspects of the invention, protocol converts are automatically, efficiently, and accurately created for packet-based NoC interconnects. The protocol converters include interfaces that have pins with names that exactly match the pin name of the external hardware elements or IP blocks, to which the pins connect. In accordance with various embodiments and aspects of the invention, a NoC description, which includes the protocol converter description, is generated using a synthesis tool during the design process.

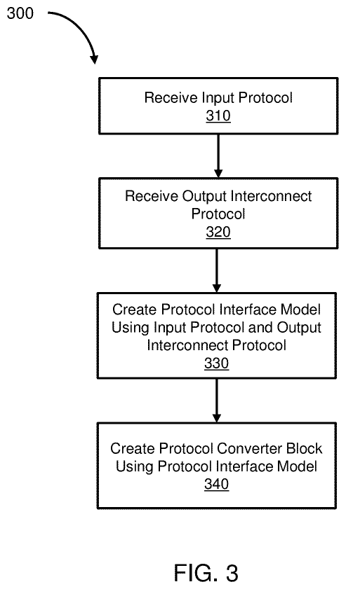

Referring now to FIG. 3 a process 300 is shown for creating a protocol converter block in accordance with various aspects and embodiments of the invention. At step 310, an input protocol is received. According to one or more aspects and embodiments of the invention, the input protocol may be read from a computer file. According to one or more aspects and embodiments of the invention, the input protocol may be read from a database, any other computer readable format, and any combination of the preceding. According to one or more aspects and embodiments of the invention, a computer file describes an interface along with the pins and the associated input protocol. According to one or more aspects and embodiments of the invention, the input protocol may be specified as a standard interface type (e.g., Advanced extensible Interface (AMBA-AXI)). According to one or more aspects and embodiments of the invention, the input protocol may be specified by a behavioral description of the interface.

At step 320, an output interconnect protocol is received. According to one or more aspects and embodiments of the invention, the output interconnect protocol may be read from a computer file. According to one or more aspects and embodiments of the invention, a computer file describes an interface along with the pins and the associated output interconnect protocol. According to one or more aspects and embodiments of the invention, the output interconnect protocol may be specified as a standard interface type (e.g., Advanced extensible Interface (AMBA-AXI)). According to one or more aspects and embodiments of the invention, the output interconnect protocol may be specified by a behavioral description of the interface.

At step 330, a protocol interface module or model is created using the input protocol and the output interconnect protocol. According to one or more aspects and embodiments of the invention, the protocol interface model is read from a computer file.

At step 340, a protocol converter block is created using the protocol interface model. According to one or more aspects and embodiments of the invention, the protocol converter block has an interface to handle bi-directional traffic flow, using input interfaces and output interfaces. The input interface of the protocol converter block implements the input protocol and the output interface implements the output interconnect protocol. According to one or more aspects and embodiments of the invention, the protocol converter converts in a bi-directional manner between input protocol and the output interconnect protocol. According to one or more aspects and embodiments of the invention, the protocol converter block translates requests and responses between the input protocol and the output interconnect protocol. According to one or more aspects and embodiments of the invention, the input protocol is packet-based. According to one or more aspects and embodiments of the invention, the output interconnect protocol is packet-based. According to one or more aspects and embodiments of the invention, creating the protocol converter block may be done locally, remotely (e.g., remote server), and any combination of the preceding.

According to one or more aspects and embodiments of the invention, the protocol converter block is created in a hardware format (e.g., HDL, Verilog, netlist, etc.). According to one or more aspects and embodiments of the invention, the protocol converter block is created in a high-level description (e.g., System Verilog, System-C, etc.).

According to one or more aspects and embodiments of the invention, one or more of the input protocols, output interconnect protocol, and protocol interface model may be contained within one or more computer files. According to one or more aspects and embodiments of the invention, one or more of the input protocols, output interconnect protocol, and protocol interface model may be contained within a database. According to one or more aspects and embodiments of the invention, one or more of the input protocols, output interconnect protocol, and protocol interface model may be contained within any computer readable format capable of storing protocols and/or models. According to one or more aspects and embodiments of the invention, one or more of the input protocols, output interconnect protocol, and protocol interface model may be stored locally, remotely, or a combination of locally and remotely.

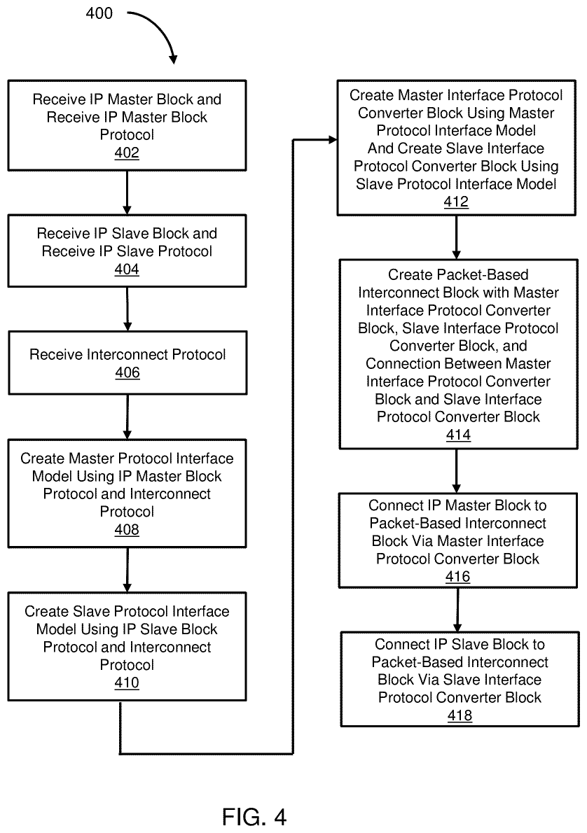

Referring now to FIG. 4 a process 400 is shown for creating a protocol converter block in accordance with various aspects and embodiments of the invention. At step 402, IP master block and IP master block protocol is received. According to one or more aspects and embodiments of the invention, the IP master block protocol may be read from a computer file. According to one or more aspects and embodiments of the invention, IP master block protocol may be the same or similar to the input protocol of step 310.

At step 404, IP slave block and IP slave protocol is received. According to one or more aspects and embodiments of the invention, the IP slave block protocol may be read from a computer file. According to one or more aspects and embodiments of the invention, IP master block protocol and IP slave block protocol are read from the same computer file. According to one or more aspects and embodiments of the invention, IP slave block protocol may be the same or similar to the input protocol of step 310.

At step 406, interconnect protocol is received. According to one or more aspects and embodiments of the invention, the interconnect protocol may be read from a computer file. According to one or more aspects and embodiments of the invention, one or more of the IP master block protocol, IP slave protocol is received, and interconnect protocol is read from one or more computer files. According to one or more aspects and embodiments of the invention, interconnect protocol may be the same or similar to the output interconnect protocol of step 320.

At step 408, a master protocol interface model is created using the IP master block protocol and the interconnect protocol. According to one or more aspects and embodiments of the invention, creating master protocol interface model may be the same or similar to creating the protocol interface of step 330. At step 410, a slave protocol interface model using IP slave block protocol and interconnect protocol is created. According to one or more aspects and embodiments of the invention, creating slave protocol interface model may be the same or similar to creating the protocol interface of step 330.

At step 412, a master interface protocol converter block is created using the master protocol interface model and a slave interface protocol converter block is created using the slave protocol interface model. According to one or more aspects and embodiments of the invention, the master interface protocol converter block and/or slave interface protocol converter block is created in a hardware format (e.g., HDL, Verilog, netlist, etc.). According to one or more aspects and embodiments of the invention, the master interface protocol converter block and/or slave interface protocol converter block is created in a high-level description (e.g., System Verilog, System-C, etc.). According to one or more aspects and embodiments of the invention, creating the master interface protocol converter block is the same or similar as creating the protocol converter block of step 340. According to one or more aspects and embodiments of the invention, creating the slave interface protocol converter block is the same or similar as creating the protocol converter block of step 340. According to one or more aspects and embodiments of the invention, the master interface protocol converter block pins are given the same respective name as the IP master block pins. A potential benefit of having the same pin names between the master interface protocol converter block pins and the IP master blocks pins is to aid in the connection of the master interface protocol convert block and the IP master block. For example, if a human is connecting the blocks, the person would know to connect the same pin names. For another example, automated software can be used to connect the same pin names.

According to one or more aspects and embodiments of the invention, the slave interface protocol converter block pins are given the same respective name as the IP slave block pins. A potential benefit of having the same pin names between the slave interface protocol converter block pins and the IP slave blocks pins is to aid in the connection of the slave interface protocol convert block and the IP slave block. For example, if a human is connecting the blocks, the person would know to connect the same pin names. For another example, automated software can be used to connect the same pin names. According to one or more aspects and embodiments of the invention, a lookup table may be used to map between a protocol and the pin names.

At step 414, a packet-based interconnect block is created that include the master interface protocol converter block, the slave interface protocol converter block, and connection between the master interface protocol converter block and the slave interface protocol converter block.

At step 416, the IP master block is connected to the packet-based interconnect block via master interface protocol converter block. At step 418, the IP slave block is connected to the packet-based interconnect block via slave interface protocol converter block.

According to one or more aspects and embodiments of the invention, packet-based interconnect block enables the IP master block to communicate with the IP slave block. The IP master block communicates with the master interface protocol converter block using the IP master block protocol. The IP slave block communicates with the slave interface protocol converter block using the IP slave block protocol. The IP master block converter converts the IP master block protocol into an interconnect protocol. The packet-based interconnect block routes the interconnect protocol to the IP slave block converter. The IP slave block converter converts the interconnect protocol to the IP slave protocol and then communicates with the IP slave block using the IP slave protocol.

According to one or more aspects and embodiments of the invention, though it is taught that a master and slave communicate via the packet-based interconnect block, any number of IP blocks may communicate using the packet-based interconnect block. For example, a central processor unit (CPU), a memory array, and a hard driver interface controller may communicate between using the packet-based interconnect block.

According to one or more aspects and embodiments of the invention, interfaces to IP blocks includes the packet-based interconnect, any number of connections (e.g., wires), and components (e.g., switches, buffers, queues, etc.).

According to one or more aspects and embodiments of the invention, the IP master block and/or the IP slave block may have a non-packet-based interface (e.g., serial interface, parallel interface, etc.), and the packet-based interconnect black has an internal packet-based interface (e.g., interconnect protocol). For example, IP master block protocol and/or IP slave block protocol may have a non-packet-based interface, and the interconnect protocol is packet based.

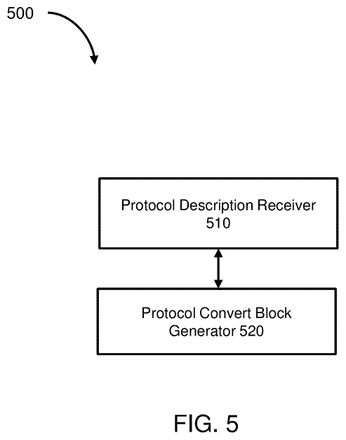

Referring now to FIG. 5 an apparatus 500 is shown for creating a protocol converter block in accordance with various aspects and embodiments of the invention. Protocol description receiver 510 receives one or more protocols. According to one or more aspects and embodiments of the invention, the protocols may be stored in one or more computer files. According to one or more aspects and embodiments of the invention, the one or more protocols may include an input protocol and an output protocol for one or more protocol converter blocks. According to one or more aspects and embodiments of the invention, protocol description receiver 510 may perform the same to similar to steps 310 and 320 of FIG. 3.

Protocol converter block generator 520 creates one or more converter blocks with the one or more protocols from receiver 510. According to one or more aspects and embodiments of the invention, protocol converter block generator 520 may perform the same or similar to steps 330 and 340 of FIG. 3. According to one or more aspects and embodiments of the invention, a master protocol interface block is created that converts between an IP master block protocol and an interconnect protocol, and a slave protocol interface block is created that converts between an IP slave block protocol and an interconnect protocol.

Certain methods according to the various aspects of the invention may be performed by instructions that are stored upon a non-transitory computer readable medium, for example a module. The non-transitory computer readable medium stores code including instructions that, if executed by one or more processors, would cause a system or computer to perform steps of the method described herein, including methods performed by a module, such as the modules described herein. The non-transitory computer readable medium includes: a rotating magnetic disk, a rotating optical disk, a flash random access memory (RAM) chip, and other mechanically moving or solid-state storage media.

Any type of computer-readable medium is appropriate for storing code comprising instructions according to various example. Some examples are one or more non-transitory computer readable media arranged to store such instructions for methods described herein. Additionally, modules may be represented by codes stored in non-transitory media or represented by hardware components that performs a specific function. Whatever machine holds non-transitory computer readable media comprising any of the necessary code may implement an example. Some examples may be implemented as: physical devices such as semiconductor chips; hardware description language representations of the logical or functional behavior of such devices; and one or more non-transitory computer readable media arranged to store such hardware description language representations.

Descriptions herein reciting principles, aspects, and embodiments encompass both structural and functional equivalents thereof. Elements described herein as coupled have an effectual relationship realizable by a direct connection or indirectly with one or more other intervening elements.

Certain examples have been described herein and it will be noted that different combinations of different components from different examples may be possible. Salient features are presented to better explain examples; however, it is clear that certain features may be added, modified and/or omitted without modifying the functional aspects of these examples as described.

Various examples are methods that use the behavior of either or a combination of machines. Method examples are complete wherever in the world most constituent steps occur. For example, and in accordance with the various aspects and embodiments of the invention, IP elements or units include: processors (e.g., CPUs or GPUs), random-access memory (RAM—e.g., off-chip dynamic RAM or DRAM), a network interface for wired or wireless connections such as ethernet, Wi-Fi, 3G, 4G long-term evolution (LTE), 5G, and other wireless interface standard radios. The IP block or element may also include various I/O interface devices, as needed for different peripheral devices such as touch screen sensors, geolocation receivers, microphones, speakers, Bluetooth peripherals, and USB devices, such as keyboards and mice, among others. By executing instructions stored in RAM devices processors perform steps of methods as described herein.

Practitioners skilled in the art will recognize many modifications and variations. The modifications and variations include any relevant combination of the disclosed features. Descriptions herein reciting principles, aspects, and embodiments encompass both structural and functional equivalents thereof. Elements described herein as “coupled” or “communicatively coupled” have an effectual relationship realizable by a direct connection or indirect connection, which uses one or more other intervening elements. Embodiments described herein as “communicating” or “in communication with” another device, module, or elements include any form of communication or link and include an effectual relationship. For example, a communication link may be established using a wired connection, wireless protocols, near-field protocols, or RFID.

The scope of the invention, therefore, is not intended to be limited to the exemplary embodiments shown and described herein. Rather, the scope and spirit of present invention is embodied by the appended claims.

What is claimed is:

1. A method for synthesis of a network-on-chip (NoC), the method comprising:
loading, in a design tool, information for the NoC, wherein the information includes a protocol for the NoC;
loading, in the design tool, first hardware information for an initiator intellectual property (IP) block that is in communication with the NoC, the first hardware information including a second protocol for the initiator IP block;
loading, in the design tool, second hardware information for a target IP block that is in communication with the NoC, the second hardware information including a third protocol for the target IP block;
generating, using the design tool, a first protocol converter description for a first protocol converter block, wherein the first protocol converter description includes a NoC interface description, wherein the NoC interface description handles conversion of protocols for transactions between the second protocol and the protocol;
generating, using the design tool, a second protocol converter description for a second protocol converter block, wherein the second protocol converter description includes a second NoC interface description, wherein the second protocol converter block handles conversion of protocols for transactions between the third protocol and the protocol;
connecting the initiator IP block to the NoC through the first protocol converter block; and
connecting the target IP block to the NoC through the second protocol converter block.

2. A method for synthesis of a network-on-chip (NoC), the method comprising:
loading, in a design tool, information for the NoC, wherein the information includes a protocol for the NoC;
loading, in the design tool, first hardware information for an initiator intellectual property (IP) block that is in communication with the NoC, the first hardware information including a second protocol for the initiator IP block;
loading, in the design tool, second hardware information for a target IP block that is in communication with the NoC, the second hardware information including a third protocol for the target IP block;
generating, using the design tool, a first protocol converter description for a first protocol converter block, wherein the first protocol converter description includes a NoC interface description, wherein the NoC interface description handles conversion of protocols for transactions between the second protocol and the protocol;
generating, using the design tool, a second protocol converter description for a second protocol converter block, wherein the second protocol converter description includes a second NoC interface description, wherein the second NoC interface description handles conversion of protocols for transactions between the third protocol and the protocol;
connecting the initiator IP block to the NoC through the first protocol converter block; and
connecting the target IP block to the NoC through the second protocol converter block.
